(19) United States
(12) Patent Application Publication
(10) Pub. No.: US 2012/0169226 A1
(43) Pub. Date: Jul. 5, 2012

(54) LIGHT-EMITTING MODULE

(75) Inventors: Wan-Ting Huang, Hsinchu (TW); Chin-Shan Chen, Hsinchu (TW); Ting-Kuo Chang, Hsinchu (TW)

(73) Assignee: AU OPTRONICS CORP., Hsinchu (TW)

(21) Appl. No.: 13/339,451

(22) Filed: Dec. 29, 2011

(30) Foreign Application Priority Data
Dec. 29, 2010 (TW) 099146721

(51) Int. Cl. H01L 51/52; H01J 7/44

(52) U.S. Cl. 315/32; 313/498

(57) ABSTRACT

A light-emitting module includes a light-emitting panel, a three-dimensional circuit board, and a positioning element. The light-emitting panel includes a light-emitting surface and a non-light-emitting surface, and the non-light-emitting surface has a plurality of panel electrode regions. The three-dimensional circuit board includes a plurality of circuit board electrode regions, the plurality of circuit board electrode regions is disposed to correspond to the plurality of panel electrode regions, and the three-dimensional circuit board is disposed on the non-light-emitting surface of the light-emitting panel, so that the plurality of circuit board electrode regions is connected electrically to the plurality of panel electrode regions. The positioning element positions the light-emitting panel and the three-dimensional circuit board.

### CROSS-REFERENCES TO RELATED APPLICATIONS

This non-provisional application claims priority under 35 U.S.C. §119(a) on Patent Application No. 99146721 filed in Taiwan, R.O.C. on 2010 Dec. 29, the entire contents of which are hereby incorporated by reference.

### BACKGROUND OF THE INVENTION

1. Technical Field

The present invention relates to a light-emitting module, and more particularly to a light-emitting module having a modularized drive circuit.

2. Related Art

In a planar display, an organic light-emitting diode (OLED) display has the features of self-illumination, wide visual angle, fast response, low power consumption, strong contrast, high brightness, thin thickness, and full color, and has a structure much simpler than that of the prior art and a temperature range of the operation environment is also larger than the prior art. As a result of these features, the OLED display has gradually attracted attention in the field of portable displays of medium or small size.

A display region and a non-display region are defined on a transparent substrate of the OLED display in the prior art. When the OLED display is connected to a drive circuit board controller, the following two products may result. One is an independent control gear with the disadvantages of high cost and heavy assembly weight, the whole device being inconvenient in use due to heavy weight in spite of its wide range of applications. The other is a built in control gear. FIG. 1 is a schematic view of an OLED display in the prior art, and FIG. 2 is a schematic view of a drive circuit module in the prior art. Please refer to FIGS. 1 and 2 simultaneously, when it will be noted that regardless of whether it is an independent control gear or a built in control gear, the design thereof lies mainly in that a track A3 is respectively introduced from electrodes A21 and A22 on two ends of a substrate A1 and is welded to an input end of a drive circuit module A4, and an output end at the other end of the drive circuit module is connected to a plug of commercial power. As a result, such an architectural design easily increases the possibility of disconnection or poor contact, and a similar problem may occur at the same time when the OLED light-emitting component is assembled with a lamp. Furthermore, the thin and light features of an OLED planar light source are difficult to highlight due to assembly complexity.

Therefore, the issue the inventor of the present invention and persons skilled in the related art intend to improve is how to simplify the structure of the OLED display, so as to reduce failure and achieve a thin and light-weight product.

### SUMMARY

In view of this the present invention is directed to a light-emitting module, which includes a light-emitting panel, a three-dimensional circuit board, and a positioning element. The light-emitting panel includes a light-emitting surface and a non-light-emitting surface, and the non-light-emitting surface has a plurality of panel electrode regions. The three-dimensional circuit board includes a plurality of circuit board electrode regions, the plurality of circuit board electrode regions is disposed to correspond to the plurality of panel electrode regions, and the three-dimensional circuit board is disposed on the non-light-emitting surface of the light-emitting panel, so that the plurality of circuit board electrode regions is connected electrically to the plurality of panel electrode regions. The positioning element is used to position the light-emitting panel and the three-dimensional circuit board.

In the present invention, the three-dimensional circuit board is used to implement drive circuit modularization, so the three-dimensional circuit board may be sleeved on the light-emitting panel to be integrated into a set of lamp module, and thus not only is the design process of the lamp assembly simplified, but the objective of achieving a thin and light lamp results. Meanwhile, lamps of various types may also be developed, such as a desk lamp, a floor lamp or an office lamp. Furthermore, in the present invention, the three-dimensional circuit board is modularized on the light-emitting panel, thus reducing the distance of border width of the light-emitting panel and facilitating the increase of the light-emitting area thereof, and the electrodes of the three-dimensional circuit board and the light-emitting panel do not need welding connection through a track, thus avoiding the risk of an internal break and simultaneously solving the problem of poor conduction of the connection between the electrodes.

The detailed features and advantages of the present invention are described below in great detail through the following embodiments, the content of the detailed description is sufficient for persons skilled in the art to understand the technical content of the present invention and to implement the present invention there accordingly. Based upon the content of the specification, the claims, and the drawings, persons skilled in the art can easily understand the relevant objectives and advantages of the present invention.

### BRIEF DESCRIPTION OF THE DRAWINGS

The present invention will become more fully understood from the detailed description given herein below for illustration only, and thus not limitative of the present invention, wherein:

FIG. 1 is a schematic view of an OLED display module in the prior art;

FIG. 2 is a schematic view of a drive circuit module in the prior art;

FIG. 3 is a schematic outside view of a first embodiment of the present invention;

FIG. 4A is a schematic view (1) of a light-emitting panel according to the first embodiment of the present invention;

FIG. 4B is a schematic view (2) of a light-emitting panel according to the first embodiment of the present invention;

FIG. 5 is a schematic cross-sectional view of the first embodiment of the present invention;

FIG. 6A is a schematic view (1) of assembling a three-dimensional circuit board according to the first embodiment of the present invention;

FIG. 6B is a schematic view (2) of assembling a three-dimensional circuit board according to the first embodiment of the present invention;

FIG. 6C is a schematic view (3) of assembling a three-dimensional circuit board according to the first embodiment of the present invention;

FIG. 7 is a schematic outside view of a second embodiment of the present invention;

FIG. 8A is a schematic view (1) of a holding element of another aspect according to the second embodiment of the present invention;

FIG. 8B is a schematic view (2) of a holding element of another aspect according to the second embodiment of the present invention;

FIG. 9 is a schematic cross-sectional view of a third embodiment of the present invention; and

FIG. 10 is a schematic cross-sectional view of a fourth embodiment of the present invention.

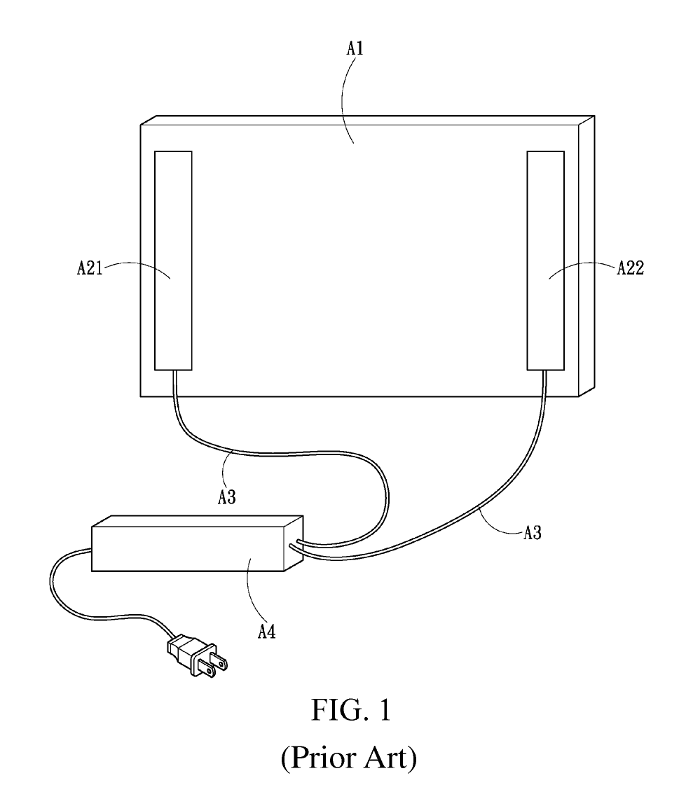

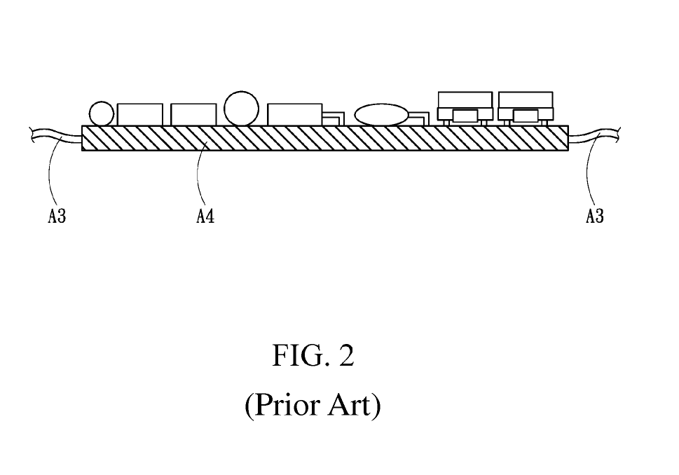

### DETAILED DESCRIPTION

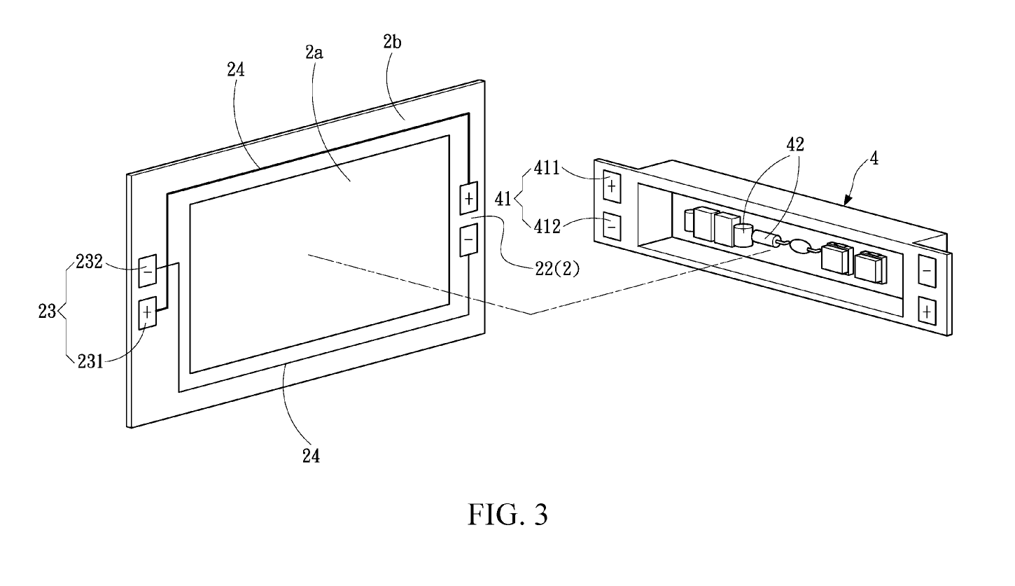

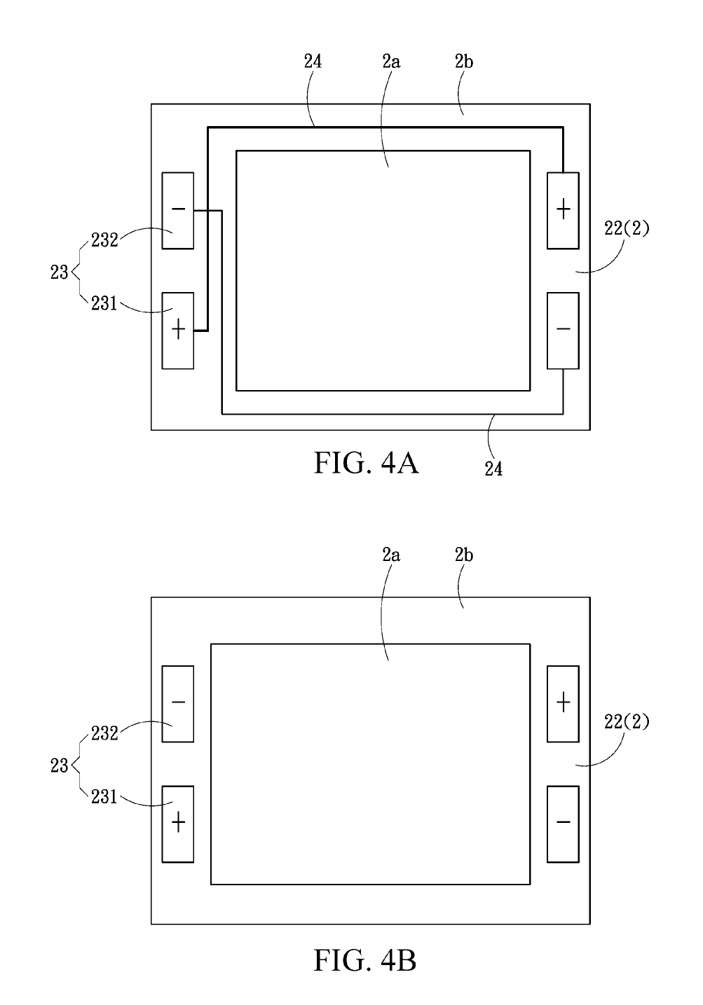

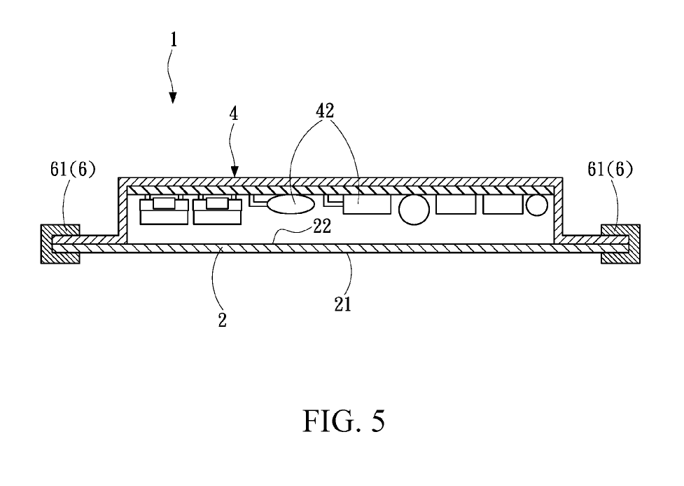

FIGS. 3, 4A and 5 illustrate a first embodiment of a light-emitting module of the present invention, in which FIG. 3 is a schematic outside view, FIG. 4A is a schematic view of a light-emitting panel, and FIG. 5 is a schematic cross-sectional diagram.

A light-emitting module 1 includes a light-emitting panel 2, a three-dimensional circuit board 4, and a positioning element 6.

The light-emitting panel 2 has a light-emitting surface 21 and a non-light-emitting surface 22, a plurality of panel electrode regions 23 is disposed on the non-light-emitting surface 22, and wires 24 are respectively connected to the corresponding panel electrode regions 23, in which the plurality of panel electrode regions 23 is composed of a plurality of panel positive electrode regions 231 and a plurality of panel negative electrode regions 232 with stagger arrangement. The plurality of panel positive electrode regions 231 and the plurality of panel negative electrode regions 232 could be staggered in two directions that are perpendicular to one another, that is, the plurality of panel positive electrode regions 231 and the plurality of panel negative electrode regions 232 could be staggered in upper/lower and left/right directions in disposition. For example, the panel positive electrode regions 231 are disposed on the left/lower and the right/upper side of the light-emitting panel 2, and the panel negative electrode region 232 are disposed on the left/upper and the right/lower side of the light-emitting panel 2. Herein, a light-emitting region 2a and a non-light-emitting region 2b are defined on a substrate of the light-emitting panel 2, in which the substrate may be a transparent glass substrate, a quartz substrate, a plastic substrate or a flexible substrate. The panel electrode regions 23 are correspondingly disposed on the non-light-emitting regions 2b, and a plurality of wires 24 (as shown in FIG. 4A), is formed on the surface of the non-light-emitting regions 2b, one of the wires 24 conducts the panel positive electrode regions 231 on the two sides of the light-emitting panel 2, and the other wire 24 conducts the panel negative electrode regions 232 on the two sides of the light-emitting panel 2.

In this embodiment, the light-emitting component of the light-emitting panel 2 is mainly composed of an OLED or an LED, and the light-emitting component is disposed on the substrate. That is to say, when the light-emitting component of the light-emitting panel 2 is composed of the OLED, the OLED and the panel electrode regions 23 may be disposed on the same surface of the substrate, and this surface faces the three-dimensional circuit board 4. In addition, the OLED of the light-emitting panel 2 is conducted with the panel electrode regions 23 through a line (not shown), formed on the surface of the substrate. The foregoing description that the light-emitting panel 2 is an OLED display panel or an LED display panel is merely an example, and the present invention is not limited to this.

The three-dimensional circuit board 4 take the shape of “n”, and a flat lamellar body extends around the three-dimensional circuit board 4 and is in the shape of a cap on the whole (as shown in FIG. 5). A plurality of circuit board electrode regions 41 is disposed on two ends of the three-dimensional circuit board 4, and a drive circuit 42 may be disposed on a recessed plane between the plurality of circuit board electrode regions 41, in which the drive circuit 42 is an output circuit with an alternating current being converted into a direct current or an output circuit with a direct current being converted into a direct current, and may be adjusted according to the electrical operation required by the light-emitting component of the light-emitting panel 2. The plurality of circuit board electrode regions 41 is composed of a plurality of circuit board positive electrode regions 411 and a plurality of circuit board negative electrode regions 412 with stagger arrangement, in which the plurality of circuit board positive electrode regions 411 and the plurality of circuit board negative electrode regions 412 could be staggered in two directions that are perpendicular to one another, that is, the plurality of circuit board positive electrode regions 411 and the plurality of circuit board negative electrode regions 412 could be staggered in upper/lower and left/right directions in disposition, like the panel electrode regions 23. Moreover, the plurality of circuit board positive electrode regions 411 is disposed to correspond to the plurality of panel positive electrode regions 231, and the plurality of circuit board negative electrode regions 412 is disposed to correspond to the plurality of panel negative electrode regions 232. The three-dimensional circuit board 4 is superposed on the light-emitting panel 2, and the plurality of circuit board electrode regions 41 is closely contacted with the plurality of panel electrode regions 23, so that the plurality of circuit board electrode regions 41 is connected electrically to the plurality of panel electrode regions 23 for the purpose of conduction, and the light-emitting panel 2 may then be driven through the three-dimensional circuit board 4.

FIG. 4B is a schematic view of the light-emitting panel of another aspect. As shown in FIG. 4B, the plurality of wires 24 may not be disposed on the surface of the non-light-emitting regions 2b of the light-emitting panel 2, and the wires 24 are integrated to the three-dimensional circuit board 4, and thus the panel positive electrode regions 231 on the two sides of the light-emitting panel 2 are conducted through the three-dimensional circuit board 4, and the panel negative electrode regions 232 on the two sides of the light-emitting panel 2 are also conducted. Therefore, on a substrate with the same size, the non-light-emitting region 2b of the light-emitting panel 2 may be reduced, and the light-emitting region 2a is increased. Furthermore, a mask wire may be omitted to reduce the cost.

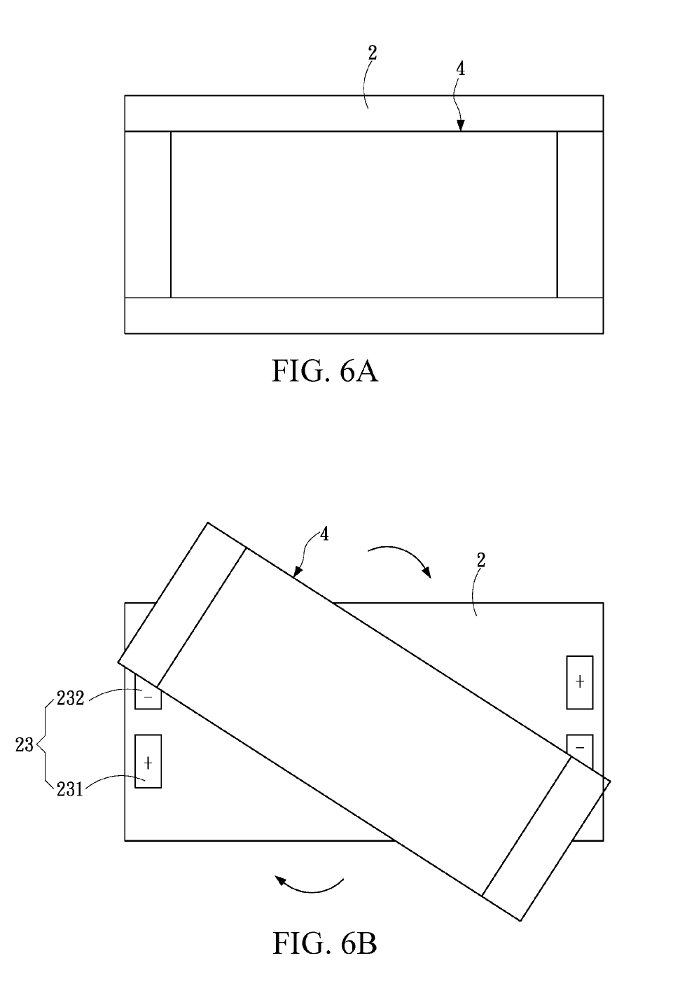

FIGS. 6A, 6B and 6C are schematic views of assembling a three-dimensional circuit board. As shown in FIGS. 6A, 6B and 6C, the plurality of panel positive electrode regions 231 and the plurality of panel negative electrode regions 232 are staggered in two directions that are perpendicular to one another, and the plurality of circuit board positive electrode regions 411 and the plurality of circuit board negative electrode regions 412 are also staggered in two directions that are perpendicular to one another, so the three-dimensional circuit board 4 may be disposed on the non-light-emitting surface 22 of the light-emitting panel 2 in a first installation direction or a second installation direction, and then the plurality of circuit board electrode regions 41 is connected electrically to the plurality of panel electrode regions 23. Herein, the first installation direction is opposite to the second installation direction about rotating 180 degrees. In other words, when the three-dimensional circuit board 4 is assembled on the light-emitting panel 2, the three-dimensional circuit board 4 may be disposed rotatably on the light-emitting panel 2 in different directions, which is not limited to the specific installation direction, thus dramatically increasing the assembly convenience.

A positioning element 6 is used to position the light-emitting panel 2 and the three-dimensional circuit board 4. In this embodiment, the positioning element 6 is a holding element 61 in the shape of reversed “U”, and when the three-dimensional circuit board 4 is superposed on the light-emitting panel 2, the holding element 61 holds a side of the light-emitting panel 2 and the three-dimensional circuit board 4, so as to fix the light-emitting panel 2 and the three-dimensional circuit board 4 to form a set of lamp module. Since the positioning element 6 is designed to enable the circuit board electrode regions 41 to be closely contacted with the panel electrode regions 23, the design that the track is introduced from the substrate of the light-emitting panel 2 in the prior art is omitted.

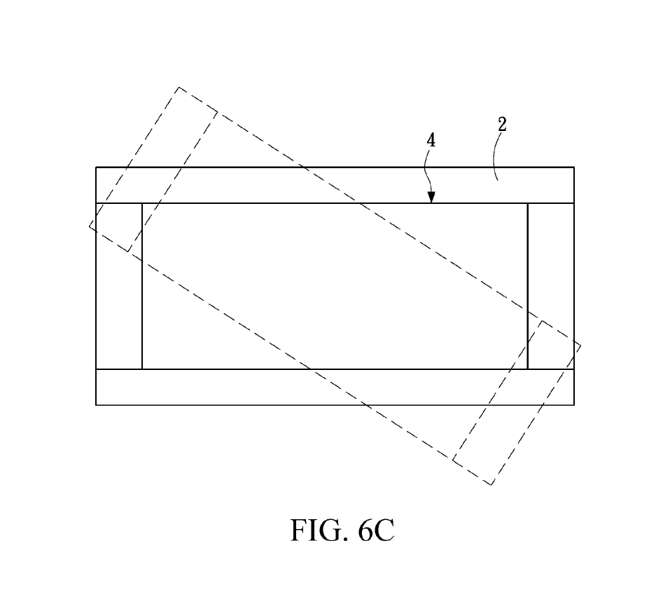

FIG. 7 illustrates a second embodiment of the present invention. The difference of this embodiment and the first embodiment lies in the electrode structure of a light-emitting panel 2 and a three-dimensional circuit board 4. In this embodiment, a plurality of panel electrode regions 23 of the light-emitting panel 2 includes a panel positive electrode region 231 and a panel negative electrode region 232, and a plurality of circuit board electrode regions 41 of the three-dimensional circuit board 4 includes a circuit board positive electrode region 411 and a circuit board negative electrode region 412. Herein, the panel positive electrode region 231 and the panel negative electrode region 232 are staggered in one direction. The circuit board positive electrode region 411 and the circuit board negative electrode region 412 are staggered in one direction, too. The three-dimensional circuit board 4 is superposed on the light-emitting panel 2, the circuit board positive electrode region 411 is closely contacted with the panel positive electrode region 231, and the circuit board negative electrode region 412 is closely contacted with the panel negative electrode region 232, so that the plurality of circuit board electrode regions 41 is connected electrically to the plurality of panel electrode regions 23 for the purpose of conduction, and then the light-emitting panel 2 may be driven through the three-dimensional circuit board 4.

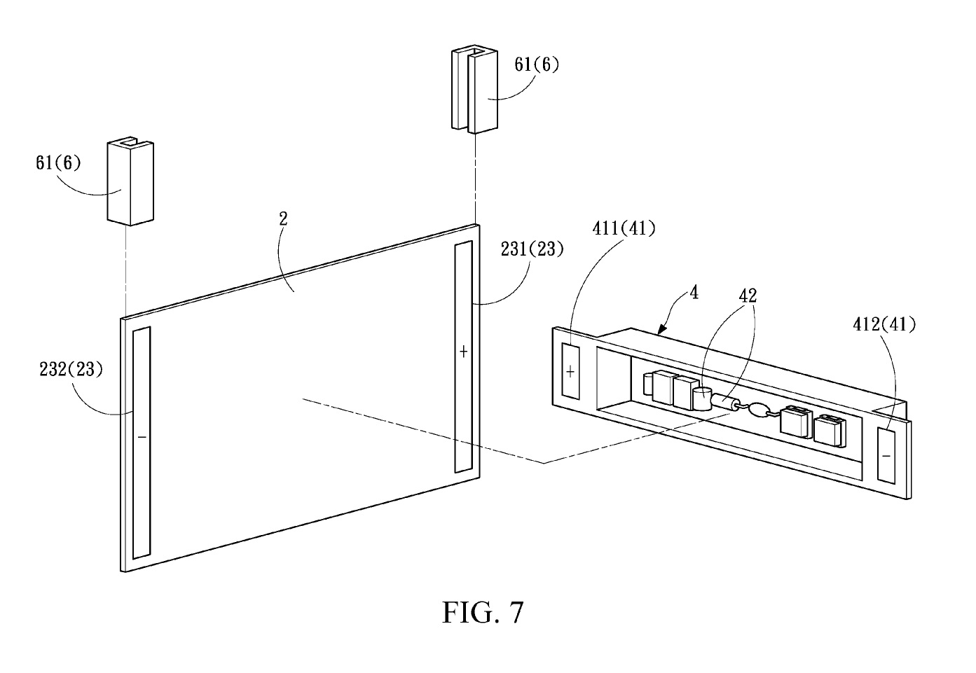

FIG. 8A illustrates another aspect of a holding element. The holding element 61 may be disposed on a rubber frame 7, so that a light-emitting module 1 of the present invention may be positioned on the rubber frame 7. In addition, FIG. 8B is a schematic view of the holding element of another aspect. As shown in FIG. 8B, the holding element 61 and the rubber frame 7 may be formed integrally.

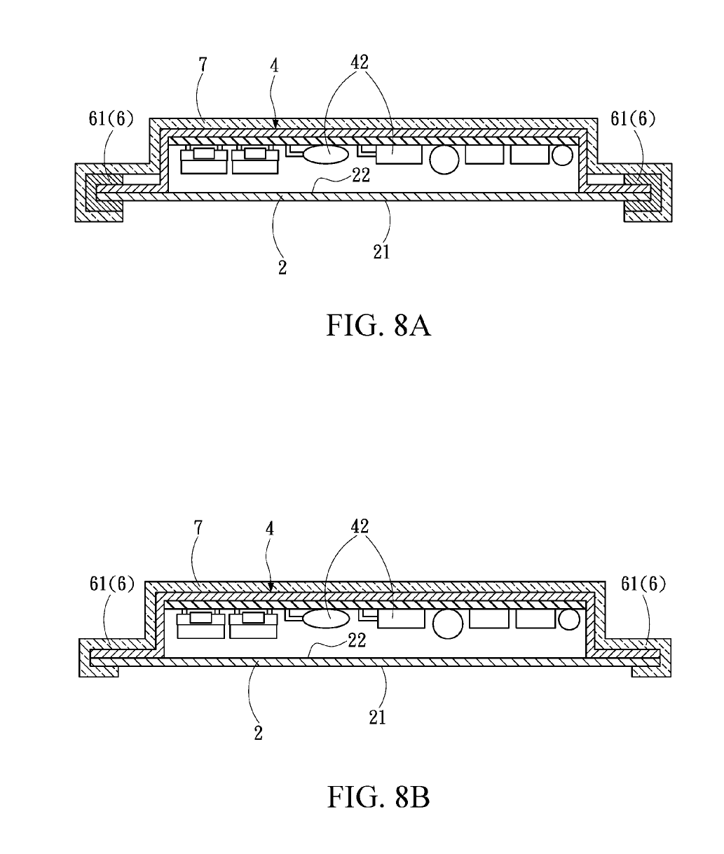

FIG. 9 illustrates a third embodiment of the present invention. The difference of this embodiment and the first embodiment lies in the structure of a positioning element 6. In this embodiment, the positioning element 6 may be a locking element 62, and a penetration hole (not shown), may be disposed on a proper location of a light-emitting panel 2 and a three-dimensional circuit board 4, so that the locking element 62 penetrates the light-emitting panel 2 and the three-dimensional circuit board 4, so as to fix the light-emitting panel 2 and the three-dimensional circuit board 4 to form a lamp module set.

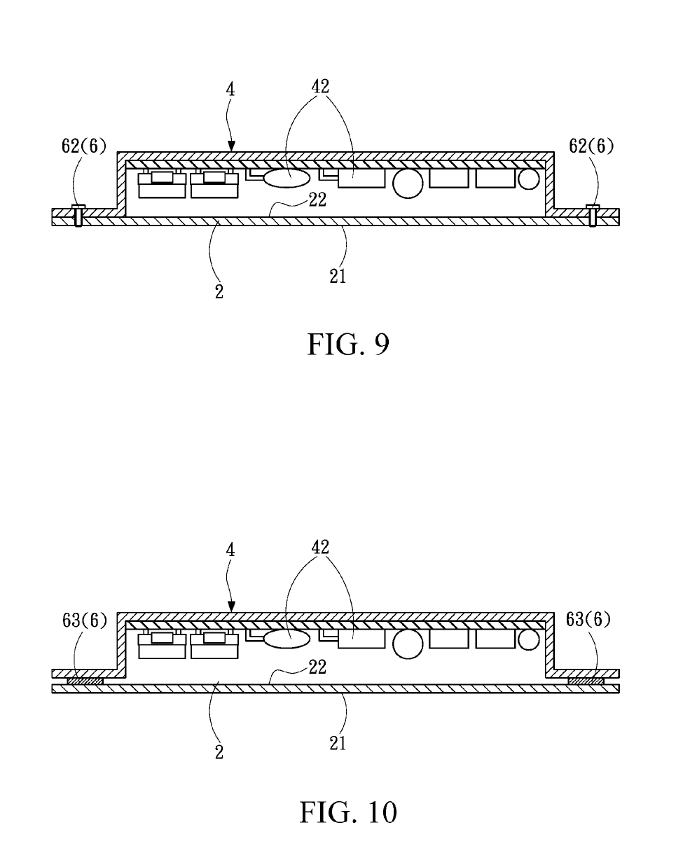

FIG. 10 illustrates a fourth embodiment of the present invention. The difference of this embodiment and the first embodiment lies in the structure of a positioning element 6. In this embodiment, the positioning element 6 may be a welding element 63, a three-dimensional circuit board 4 is superposed on a light-emitting panel 2, the welding element 63 is disposed between a corresponding plurality of circuit board electrode regions 41 and a plurality of panel electrode regions 23, a plurality of circuit board positive electrode regions 411 and a plurality of panel positive electrode regions 231 are fixedly welded through the welding element 63, and a plurality of circuit board negative electrode regions 412 and a plurality of panel negative electrode regions 232 are fixedly welded through the welding element 63, so as to connect electrically the plurality of circuit board electrode regions 41 with the plurality of panel electrode regions 23, and to achieve the objective of fixing the light-emitting panel 2 and the three-dimensional circuit board 4.

In the present invention, the three-dimensional circuit board is used to achieve the drive circuit modularization, and is directly sleeved on the light-emitting panel to simplify the design process of lamp assembly, thus achieving the objective of a thin and light lamp, which may be applicable to the lamps of various types such as a desk lamp, a floor lamp or an office lamp. Furthermore, in the present invention, the three-dimensional circuit board is modularized on the light-emitting panel, thus reducing the distance of border width of the light-emitting panel and facilitating the increase of the light-emitting area thereof, and the electrodes of the three-dimensional circuit board and the light-emitting panel do not need welding connection through a track, thus avoiding the risk of an internal break and solving the problem of poor conduction of the connection between the electrodes at the same time.

While the present invention has been described by the way of example and in terms of the preferred embodiments, it is to be understood that the invention need not to be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A light-emitting module, comprising:
a light-emitting panel, comprising a light-emitting surface and a non-light-emitting surface, wherein the non-light-emitting surface has a plurality of panel electrode regions;
a three-dimensional circuit board, comprising a plurality of circuit board electrode regions, wherein the plurality of circuit board electrode regions is disposed to correspond to the panel electrode regions, the three-dimensional circuit board is disposed on the non-light-emitting surface of the light-emitting panel, so that the plurality of circuit board electrode regions is connected electrically to the plurality of panel electrode regions; and
a positioning element, used to position the light-emitting panel and the three-dimensional circuit board.

2. The light-emitting module according to claim 1, wherein the light-emitting surface has a light-emitting region and a non-light-emitting region, and the panel electrode regions correspond to the non-light-emitting region.

3. The light-emitting module according to claim 2, wherein the panel electrode regions comprise at least one panel positive electrode region and at least one panel negative electrode region with stagger arrangement.

4. The light-emitting module according to claim 3, wherein the at least one panel positive electrode region and the at least one panel negative electrode region are staggered in one direction.

5. The light-emitting module according to claim 3, wherein the at least one panel positive electrode region and the at least one panel negative electrode region are staggered in two directions that are perpendicular to one another.

6. The light-emitting module according to claim 1, wherein the circuit board electrode regions comprise at least one circuit board positive electrode region and at least one circuit board negative electrode region with stagger arrangement.

7. The light-emitting module according to claim 6, wherein the at least one circuit board positive electrode region and the at least one circuit board negative electrode region are staggered in one direction.

8. The light-emitting module according to claim 6, wherein the at least one circuit board positive electrode region and the at least one circuit board negative electrode region are staggered in two directions that are perpendicular to one another.

9. The light-emitting module according to claim 1, wherein the positioning element is a holding element, holding at a side of the light-emitting panel and the three-dimensional circuit board.

10. The light-emitting module according to claim 9, wherein the holding element is located on a rubber frame.

11. The light-emitting module according to claim 1, wherein the positioning element is a locking element, penetrating the light-emitting panel and the three-dimensional circuit board.

12. The light-emitting module according to claim 1, wherein the positioning element is a welding element, connected electrically to the circuit board electrode regions and the panel electrode regions.

13. The light-emitting module according to claim 1, wherein the three-dimensional circuit board is used to drive the light-emitting panel.

14. The light-emitting module according to claim 1, wherein the three-dimensional circuit board has a drive circuit, and the drive circuit is an output circuit with an alternating current being converted into a direct current or an output circuit with a direct current being converted into a direct current.

15. The light-emitting module according to claim 1, wherein the light-emitting panel is an organic light-emitting display (OLED) panel.

16. The light-emitting module according to claim 1, wherein the three-dimensional circuit board is disposed in a first installation direction and a second installation direction, and the first installation direction is opposite to the second installation direction.
